(19) United States
(12) Patent Application Publication
(10) Pub. No.: US 2023/0047740 A1
(43) Pub. Date: Feb. 16, 2023

(54) VERTICAL CAVITY SURFACE EMITTING LASER ILLUMINATOR PACKAGE WITH EMBEDDED CAPACITOR

(71) Applicant: Lumentum Operations LLC, San Jose, CA (US)

(72) Inventors: Siu Kwan CHEUNG, San Jose, CA (US); Wei SHI, San Jose, CA (US); Hao HUANG, San Jose, CA (US); Lijun ZHU, Pleasanton, CA (US); Huanlin ZHU, San Jose, CA (US)

(21) Appl. No.: 17/449,612

(22) Filed: Sep. 30, 2021

Related U.S. Application Data
(60) Provisional application No. 63/260,221, filed on Aug. 12, 2021.

(51) Int. Cl. H01S 5/042; H01L 49/02

(52) U.S. Cl. CPC H01S 5/042; H01L 28/40; H01S 5/183

(57) ABSTRACT

In some implementations, a vertical cavity surface emitting laser (VCSEL) package may include a substrate. The VCSEL package may include a VCSEL disposed on a surface of the substrate. The VCSEL package may include a VCSEL driver disposed on the surface of the substrate. The VCSEL package may include an embedded capacitor electrically connected to the VCSEL and the VCSEL driver. The embedded capacitor may be formed from a subset of layers of the substrate. The capacitor may be associated with a first capacitance that is different from a second capacitance of at least one other capacitor associated with the substrate.

### CROSS REFERENCE TO RELATED APPLICATION

This Patent Application claims priority to U.S. Provisional Pat. Application No. 63/260,221, filed on Aug. 12, 2021, and entitled “VERTICAL CAVITY SURFACE EMITTING LASER ILLUMINATOR SUBSTRATE WITH AN EMBEDDED CAPACITOR.” The disclosure of the prior Application is considered part of and is incorporated by reference into this Patent Application.

### TECHNICAL FIELD

The present disclosure relates generally to lasers and to a vertical cavity surface emitting laser with one or more embedded capacitors.

### BACKGROUND

A vertical-emitting device, such as a bottom-emitting or top-emitting vertical-cavity surface-emitting laser (VCSEL), is a laser in which a laser beam is emitted in a direction perpendicular to a surface of a substrate (e.g., vertically from a surface of a semiconductor wafer). A VCSEL device may be used for three-dimensional sensing, gesture recognition, range detection, or communication, among other examples. A typical VCSEL includes epitaxial layers (epi layers) grown on a substrate. The epitaxial layers may include, for example, a pair of reflectors (e.g., a pair of distributed Bragg reflectors (DBRs)), an active region, an oxidation layer, and/or the like. Other layers may be formed on or above the epitaxial layers, such as one or more dielectric layers, metal layers, and/or the like. A VCSEL package may include a substrate onto which is attached a VCSEL, a driver, and a decoupling capacitor. A VCSEL array may provide multiple emitting sources (e.g., VCSEL elements) on a single chip for emitting a single beam or multiple discrete beams.

### SUMMARY

According to some implementations, a VCSEL package includes a substrate; a VCSEL disposed on a surface of the substrate; a VCSEL driver disposed on the surface of the substrate; and an embedded capacitor electrically connected to the VCSEL and the VCSEL driver, wherein the embedded capacitor is formed from a subset of layers of the substrate, and wherein the capacitor is associated with a first capacitance that is different from a second capacitance of at least one other capacitor associated with the substrate.

According to some implementations, a VCSEL substrate includes a first set of layers including one or more trace routing connections; a second set of layers forming a metal-insulator-metal (MIM) capacitor, wherein the second set of layers comprises one or more high dielectric thin layers alternating with one or more ground layers; and a surface, formed, at least in part, from at least one layer of the second set of layers, to receive at least one electro-optical component, wherein the at least one electro-optical component includes at least one of a driver, a VCSEL chip, or a decoupling capacitor.

According to some implementations, a VCSEL package includes a substrate; a VCSEL disposed on a surface of the substrate; a VCSEL driver disposed on the surface of the substrate; and a set of embedded capacitors electrically connected to the VCSEL and the VCSEL driver, wherein the set of embedded capacitors is formed from a subset of layers of the substrate, wherein an embedded capacitor, of the set of embedded capacitors, is associated with a first capacitance that is different from a second capacitance of another capacitor of the set of embedded capacitors.

### BRIEF DESCRIPTION OF THE DRAWINGS

FIG. 1 is a diagram of an example vertical cavity surface emitting laser (VCSEL) package with an embedded multi-layer metal-insulator-metal (MIM) capacitor, as described herein.

FIG. 2 is a diagram of an example VCSEL package with multiple embedded MIM capacitors, as described herein.

FIG. 3 is a diagram of an example inductance looping path in a VCSEL, as described herein.

FIG. 4 is a diagram of an example VCSEL package with an embedded MIM capacitor and an embedded decoupling capacitor, as described herein.

FIGS. 5-7 are diagrams of example VCSEL packages with multiple embedded MIM capacitors, as described herein.

FIGS. 8A-8C are diagrams of an example embedded capacitor array for a VCSEL array, as described herein.

FIGS. 9A-9B are diagrams of an example embedded capacitor array for a VCSEL array, as described herein.

### DETAILED DESCRIPTION

The following detailed description of example implementations refers to the accompanying drawings. The same reference numbers in different drawings may identify the same or similar elements.

As described above, a VCSEL package may have a decoupling capacitor attached to a surface of a substrate. The decoupling capacitor can be connected in parallel with a voltage supply and a ground for the VCSEL package. A VCSEL chip (e.g., a wafer on which a VCSEL is formed), a driver chip (e.g., a wafer on which a driver is formed), and the decoupling capacitor of the VCSEL package may, when current is applied, experience current looping. To reduce an impact of current looping, an electrical length (of an inductive current loop) and associated looping area may be reduced, which reduces inductance by positioning the decoupling capacitor as closely as possible to the VCSEL chip and the driver chip. However, a low impedance bandwidth, provided in connection with using a decoupling capacitor, is limited to a bandwidth that corresponds to a capacitance of the decoupling capacitor (e.g., a single surface mount (SMT) capacitor). Accordingly, it may be desirable to have multiple decoupling capacitors to provide a low impedance bandwidth across a wide operation bandwidth of the VCSEL chip. Having low impedance across the operation bandwidth results in improved efficiency and performance for the VCSEL chip during, for example, high current operation. Moreover, having low impedance across a wide bandwidth can support higher harmonics for pulse switched operations, such as in indirect time of flight (iToF) sensing or direct time of flight (dToF) sensing pulse mode operation.

With increasing miniaturization of sensor systems, monitoring systems, or communications systems, which may include VCSEL packages, a surface of a substrate of a VCSEL package may only have space for a single decoupling capacitor in parallel with the voltage supply and the ground. When the VCSEL chip and the decoupling capacitor are connected in series with the driver chip and the ground, an impedance of the decoupling capacitor will have a voltage drop along the current path associated with current discharged from the decoupling capacitor, thereby reducing efficiency and increasing a temperature of the VCSEL package, which may be undesirable. Thus, it may be desirable to provide a VCSEL package with multiple capacitors, which have multiple different capacitances, positioned in parallel and as close to a VCSEL chip and VCSEL driver of the VCSEL package as is possible. In some use cases, such as for fast switching operation, the decoupling capacitor may act as a radio frequency (RF) power source with charges supplied by the power source (the power supply may have a slow response and may not have fast switching for Time of Flight (ToF) operations).

Some implementations described herein provide a VCSEL package with at least one embedded capacitor. For example, a capacitor may be embedded in a substrate of the VCSEL package in addition to a decoupling capacitor on a surface of the substrate, thereby increasing a low impedance bandwidth of the VCSEL package and supporting increased miniaturization of VCSEL packages. Additionally, or alternatively, multiple capacitors may be embedded in the substrate of the VCSEL package with or without a surface decoupling capacitor (or discrete capacitor or multi-layer ceramic (MLCC) capacitor) to provide an increased low impedance bandwidth for the VCSEL package. In some implementations, the one or more embedded capacitors in the substrate may be configured to support a two-dimensional matrix-addressable VCSEL array, which has a dense inputs and outputs, disposed on a surface of the substrate, thereby supporting output of one or more multiple discrete beams from the VCSEL package with a low impedance bandwidth across an operation bandwidth of the VCSEL package with reduced available space in a small package.

In these cases, by embedding a capacitor in the substrate with an ultra-thin dielectric layer, the VCSEL package may have a relatively small looping area, thereby maintaining low inductance due to, for example, to partial cancellation of mutual inductance (when parallel currents flowing in opposite directions are brought closer to each other, such as with a thin dielectric layer placed directly underneath a cathode of a VCSEL that is also contributed by an embedded MIM capacitor structure). The inductance is reduced by a shorter current loop or electrical length and the cancellation effect of mutual inductance or opposite magnetic flux. Implementations described herein may enable faster rise and fall times for high-speed operation, which enables improved accuracy for measurements performed using implementations described herein. Moreover, by providing additional capacitance and support for a wider bandwidth with a lower impedance (e.g., than is achieved with only a surface-mounted decoupling capacitor), this broadens a low impedance bandwidth, improves efficiency, and reduces a likelihood of excess temperature generation for the VCSEL package.

In some implementations, the embedded capacitor, which includes an ultra-thin dielectric layer followed immediately by a ground plane, is placed directly underneath a cathode of the VCSEL, where a driving current of the VCSEL-driver-capacitor loop flows in an opposite direction of a current through a ground plane associated with the dielectric layer. This can reduce inductance due to magnetic flux cancellation of mutual inductance. The ultra-thin dielectric (e.g., which may have a thickness between 0.5 micrometers (µm) and 1 µm) may be placed immediately underneath the cathode and then followed by a ground plane, such that the looping area is the minimized and the directions of the currents between the cathode and the ground plane are in the opposite sense.

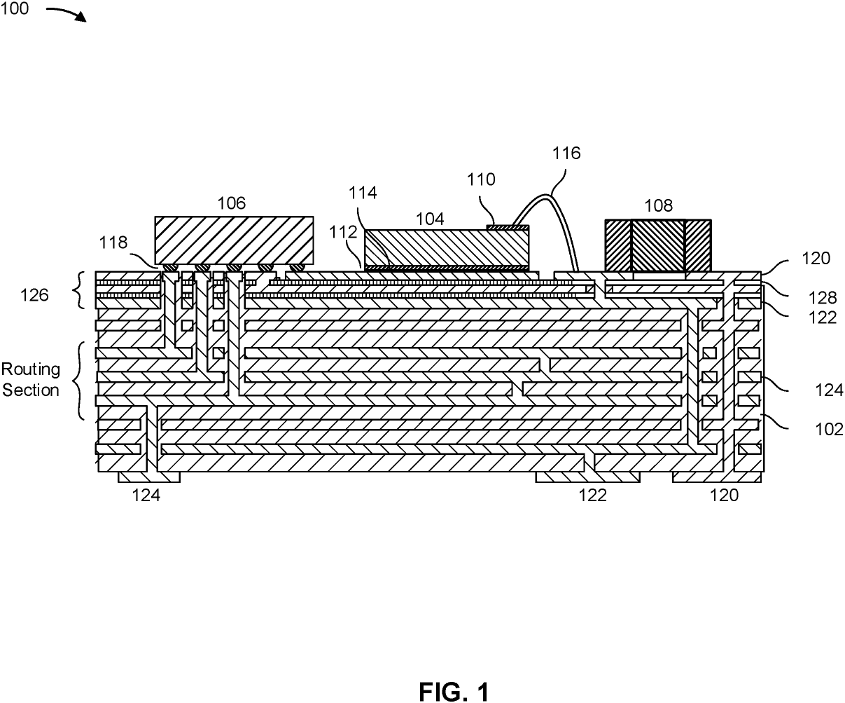

FIG. 1 is a diagram of an example of a VCSEL package 100 with an embedded multi-layer MIM capacitor. As shown in FIG. 1, a substrate 102 may have a top surface onto which is mounted a VCSEL chip 104, a driver chip 106, and a decoupling capacitor 108 (e.g., a surface mounted ceramic capacitor). A ground path 120, a power path 122, a control path 124, and an embedded multi-layer capacitor 126 may be embedded in substrate 102 with a very thin dielectric layer 128 placed directly underneath the cathode 112 of the VCSEL chip to from the first MIM capacitor. Additional single or plural MIM capacitors with different dielectric layer thicknesses can be formed below the first MIM structure, as described in more detail herein. Substrate 102 may be a multi-layer substrate that includes one or more layers associated with power path 122, one or more layers associated with ground path 120, and one or more layers associated with control path 124, which may be termed a “routing section” of substrate 102. In some implementations, power path 122 may include one or more power line traces embedded in substrate 102 to connect one or more embedded multi-layer capacitors 126 to one or more electro-optical components (e.g., VCSEL chip 104, driver chip 106, or decoupling capacitor 108). In some implementations, control path 124 may include one or more trace routing connections and/or one or more vias connecting different layers of substrate 102.

In some implementations, substrate 102 may be a multi-layer printed circuit board (PCB) substrate. For example, substrate 102 may include dielectric layers, metallization layers (and vias connected thereto), insulator layers, or structural layers, among other examples. VCSEL chip 104 may include one or more layers of material forming a VCSEL and may be disposed on the top surface of substrate 102. For example, VCSEL chip 104 may include an anode 110 (e.g., an anode pad) on a top of VCSEL chip 104 and a cathode 112 (e.g., a cathode pad) on a bottom of VCSEL chip 104. Cathode 112 may bind, at a bind line 114, to a top of substrate 102 (and the embedded multi-layer capacitor 126 embedded therein). Alternatively, cathode 112 may be a part of substrate 102 and/or form a part of embedded multi-layer capacitor 126, and may receive VCSEL chip 104 during manufacture or assembly. Anode 110 may be electrically connected to power path 122 and decoupling capacitor 108 via a bond wire 116.

In some implementations, driver chip 106 may be a VCSEL driver disposed on the top surface of substrate 102 and connected to control path 124 via a set of ball joints 118 (e.g., solder balls forming a ball grid or ball grid array). For example, driver chip 106 may be electrically connected to VCSEL chip 104 via control path 124, thereby enabling driver chip 106 to drive VCSEL chip 104. In some implementations, decoupling capacitor 108 is disposed on the top surface of substrate 102 and electrically connects power path 122 with ground path 120. For example, bond wire 116 may connect VCSEL chip 104 to power path 122 and to decoupling capacitor 108 (and to ground path 120 via decoupling capacitor 108).

In some implementations, embedded multi-layer capacitor 126 may be an embedded capacitor that is electrically connected to VCSEL chip 104 and driver chip 106. In some implementations, embedded multi-layer capacitor 126 may be formed from a subset of layers of substrate 102. For example, embedded multi-layer capacitor 126 may be formed from one or more layers of ground path 120 and/or power path 122 alternating or interlaced with one or more dielectric layers 128. In some implementations, dielectric layers 128 may be high dielectric thin layers. For example, dielectric layers 128 may include 0.6 micrometer (µm) thick barium-titanium-oxide (BaTiO₃) layers. In some implementations, dielectric layers 128 may have a dielectric constant greater than a dielectric threshold and a thickness of less than a thickness threshold, such as less than 10 µm, less than 1 µm, or less than 0.75 µm, among other examples.

Additionally, or alternatively, dielectric layers 128 may include another dielectric material. For example, dielectric layers 128 may include silicon dioxide (SiO₂), silicon nitride (Si₃N₄), titanium dioxide (TiO₂), or barium-strontium-titanate (BST) (BaₓSr₁₋ₓTiO₃) layers, among other examples of layer materials. In some implementations, a thin film dielectric layer 128 may be used for a thin-film capacitor (“TFCP” or “TFCP capacitor”) type of embedded multi-layer capacitor. For example, embedded multi-layer capacitor 126 may have a total thickness of less than 50 µm (e.g., including a top electrode copper (Cu) layer, a thin film dielectric layer 128, and a bottom electrode nickel (Ni) layer) and may have a capacitance of greater than or equal to 1.0 micro-Farad (µF) per square centimeter (cm²) (µF/cm²). In some implementations, a thin layer of substrate 102 may be disposed between metal layers (e.g., layers of ground path 120) of embedded multi-layer capacitor 126 as a dielectric layer 128. In this way, the VCSEL package 100 may achieve lower inductance than is achieved without the thin layer of substrate 102 and the embedded multi-layer capacitor 126, thereby improving switching speed for the VCSEL package 100.

In some implementations, embedded multi-layer capacitor 126 may form at least a portion of the top surface of substrate 102. For example, a dielectric layer directly under VCSEL chip 104 may form a portion of embedded multi-layer capacitor 126, thereby resulting in embedded multi-layer capacitor 126 forming a portion of the top surface of substrate 102 to which VCSEL chip 104 attaches. Additionally, or alternatively, the dielectric layer may be directly under a cathode 112 (for a surface emitting VCSEL) or anode 110 of VCSEL chip 104 (for a bottom emitting VCSEL), such that the cathode 112 or anode 110 is disposed on the top surface of substrate 102 and the VCSEL chip 104 attaches to the cathode 112 or anode 110. Additionally, or alternatively, a ground layer forming a portion of ground path 120 may form a portion of a top surface of substrate 102 and may form a portion of embedded multi-layer capacitor 126.

In some implementations, embedded multi-layer capacitor 126 may be arranged in parallel with decoupling capacitor 108. In this case, based on embedded multi-layer capacitor 126 in parallel with decoupling capacitor 108, a low-impedance bandwidth of the VCSEL package 100 (e.g., for high current operation) is widened with improved efficiency (e.g., lower resistivity loss) relative to a configuration with only a decoupling capacitor or with a decoupling capacitor in series with an embedded multi-layer capacitor. Based on a thickness, material choice, or shape of the layers that form embedded multi-layer capacitor 126, embedded multi-layer capacitor 126 may have a first capacitance that is different from at least one other capacitor associated with substrate 102, such as decoupling capacitor 108 (e.g., a surface mounted decoupling capacitor or an embedded decoupling capacitor, as described herein) or another MIM capacitor, among other examples. In this way, by embedding a multi-layer capacitor 126 in substrate 102, rather than adding additional surface-mounted decoupling capacitors to provide additional capacitance values, the VCSEL package 100 can achieve increased capacitance and be increasingly miniaturized, which may enable a higher density of VCSEL packages 100 in a device or VCSEL packages 100 to be included in increasingly miniaturized devices. Furthermore, using an embedded multi-layer capacitor 126 may reduce cost relative to using additional decoupling capacitors to add capacitance for the VCSEL package 100.

As indicated above, FIG. 1 is provided as an example. Other examples may differ from what is described with regard to FIG. 1.

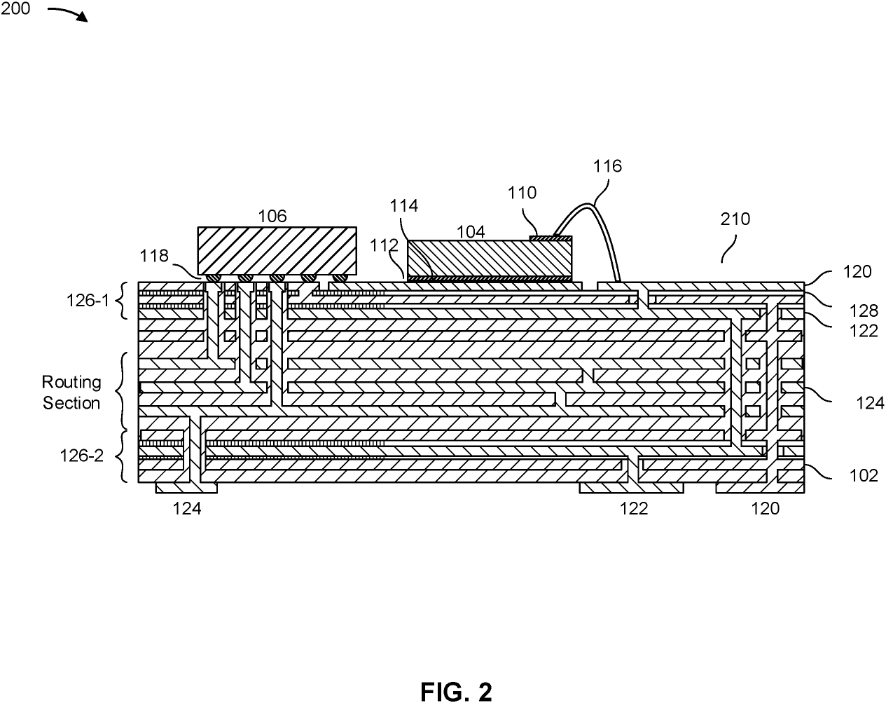

FIG. 2 is a diagram of an example of a VCSEL package 200 with multiple embedded MIM capacitors. As shown in FIG. 2, the substrate 102 includes a VCSEL chip 104 and a driver chip 106, but does not include a decoupling capacitor 108 on the top surface of substrate 102, as shown by reference number 210. In this case, embedded in substrate 102 are multiple embedded multi-layer capacitors 126 to replace decoupling capacitor 108 and/or other multi-layer ceramic capacitors (“MLCCs” or “MLCC capacitors”) surface-mounted to substrate 102. For example, a first embedded multi-layer capacitor 126-1 may be disposed above the routing section of substrate 102 (e.g., forming at least a portion of the top surface of substrate 102 or disposed below the top surface of 102) and a second embedded multi-layer capacitor 126-2 may be disposed below the routing section of substrate 102 (e.g., multi-layer capacitor 126-1 and 126-2 may sandwich the routing section of substrate 102).

In some implementations, the embedded multi-layer capacitors 126 may have different capacitance values. For example, first embedded multi-layer capacitor 126-1 may have a first size, dielectric thickness, material composition, or other property that results in a first capacitance value, and second embedded multi-layer capacitor 126-2 may have a second size, dielectric thickness, material composition, or other property that results in a second capacitance value. In this case, based on having embedded multi-layer capacitors 126 with multiple different capacitance values, the VCSEL package 200 achieves a widened low-inductance bandwidth, which may improve performance of the VCSEL package 200 relative to another VCSEL package with a narrower low-inductance bandwidth. The embedded capacitor 126-2 has the same layer structure where the capacitance is formed by sandwiching a dielectric layer between the ground plane and the power plane. This embedded capacitor 126-2 may suppress noise from power supply further away from the VCSEL chip.

As indicated above, FIG. 2 is provided as an example. Other examples may differ from what is described with regard to FIG. 2.

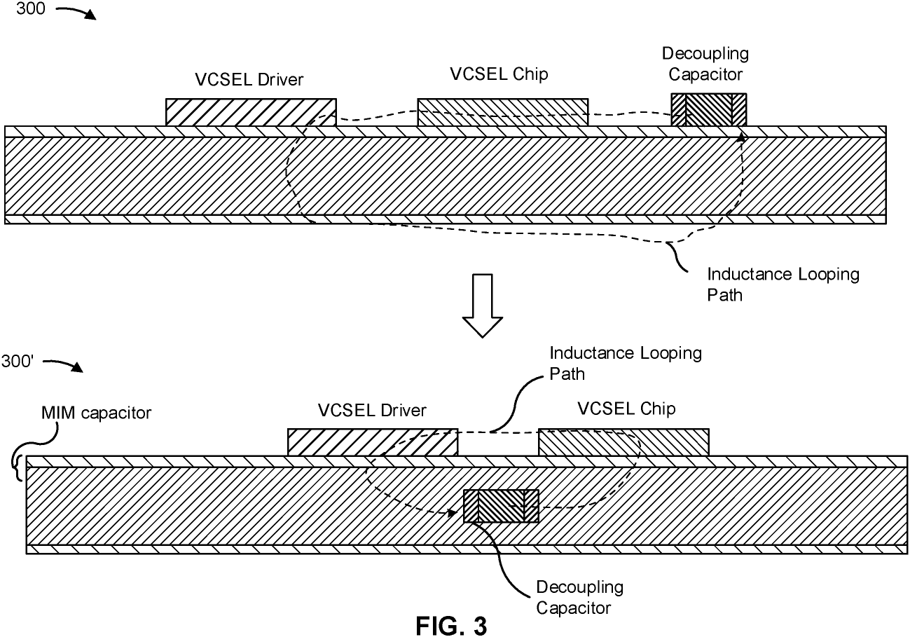

FIG. 3 is a diagram of examples 300/300' of an inductance looping path in a VCSEL. As shown in FIG. 3, a first VCSEL package 300 may include a VCSEL driver, a VCSEL chip, and a decoupling capacitor at a surface of a substrate. As further shown in FIG. 3, a second VCSEL package 300' may include a VCSEL driver and a VCSEL chip at the surface of the substrate, a decoupling capacitor embedded within the substrate, and an embedded multi-layer capacitor (e.g., an MIM capacitor) embedded at a top surface of the second VCSEL package 300'. As shown in FIG. 3, based on the second VCSEL package 300' having the decoupling capacitor embedded within the substrate and the embedded multi-layer capacitor, the second VCSEL package 300' may have a shorter inductance looping path, and thus a smaller looping area that stores less magnetic flux, than the first VCSEL package 300. Based on reducing the inductance looping path or looping area, second VCSEL package 300' has a smaller looping area than the first VCSEL package 300, thereby achieving a lower inductance (e.g., less than a threshold amount of inductance) and faster speed.

As indicated above, FIG. 3 is provided as an example. Other examples may differ from what is described with regard to FIG. 3.

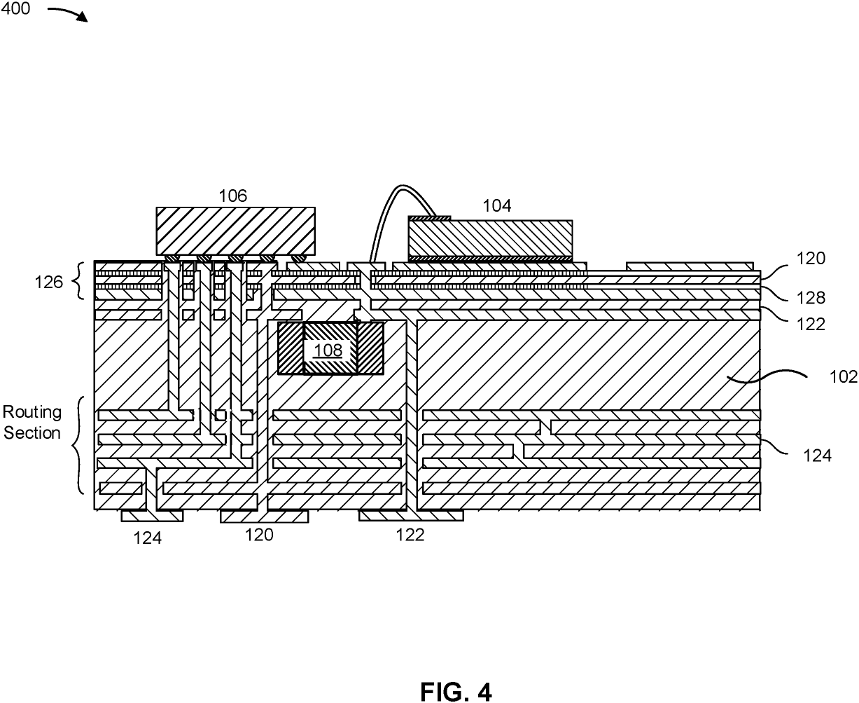

FIG. 4 is a diagram of an example of a VCSEL package 400 with an embedded MIM capacitor and an embedded decoupling capacitor. As shown in FIG. 4, the VCSEL package 400 may include a substrate 102, a VCSEL chip 104, a driver chip 106, a decoupling capacitor 108, and an embedded multi-layer capacitor 126 (e.g., a MIM capacitor). As shown, the decoupling capacitor 108 may be embedded within substrate 102 rather than disposed on a top surface of substrate 102, and the embedded multi-layer capacitor 126 may be disposed between the decoupling capacitor 108 and the top surface of the substrate. Disposing the embedded MIM capacitor 126 directly underneath the cathode of the VCSEL chip 104 may enable a first thin dielectric layer to reduce inductance by mutual inductance. In some implementations, the VCSEL package 400 may correspond to second VCSEL package 300' shown in FIG. 3.

As indicated above, FIG. 4 is provided as an example. Other examples may differ from what is described with regard to FIG. 4.

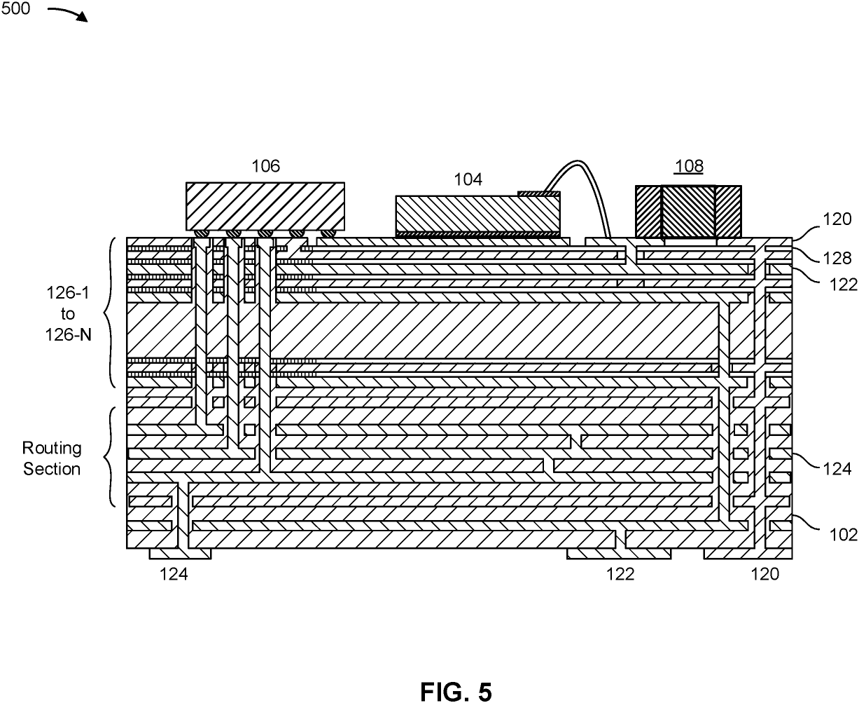

FIG. 5 is a diagram of an example of a VCSEL package 500 with multiple embedded MIM capacitors. As shown in FIG. 5, the VCSEL package 500 may include a substrate 102, a VCSEL chip 104, a driver chip 106, a decoupling capacitor 108, and a set of embedded multi-layer capacitors 126-1 through 126-N. For example, a first set of layers of substrate 102 may form one or more trace routing connections of the routing section, a second set of layers of substrate 102 may form a first embedded multi-layer capacitor 126-1, and a third set of layers of substrate 102 may form a second embedded multi-layer capacitor 126-2. Additionally, or alternatively, one or more additional sets of layers may form one or more additional multi-layer capacitors 126. In this case, multiple embedded multi-layer capacitors 126 are stacked within substrate 102 between the top surface of substrate 102 and the routing section of substrate 102. In some implementations, the embedded multi-layer capacitors 126-1 and 126-2 may have different capacitance values. For example, embedded multi-layer capacitor 126-1 may have a first capacitance value and embedded multi-layer capacitor 126-2 may have a second capacitance value, thereby achieving a widened low-inductance bandwidth for the VCSEL package 500. Moreover, stacking multiple embedded multi-layer capacitors 126 may achieve a higher level of capacitance closer to surface electro-optic components (e.g., VCSEL chip 104, driver chip 106, and decoupling capacitor 108 at the top surface of substrate 102) while positioning the routing section closer to a bottom surface of the substrate 102.

As indicated above, FIG. 5 is provided as an example. Other examples may differ from what is described with regard to FIG. 5.

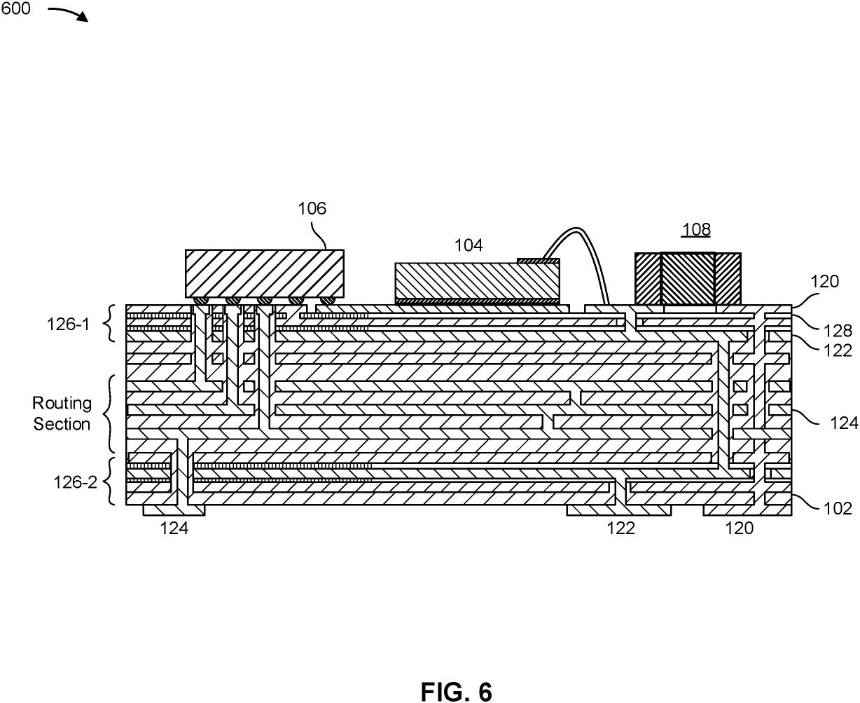

FIG. 6 is a diagram of an example associated with a VCSEL package 600 with multiple embedded MIM capacitors. As shown in FIG. 6, the VCSEL package 600 may include a substrate 102, a VCSEL chip 104, a driver chip 106, a decoupling capacitor 108, and a set of embedded multi-layer capacitors 126-1 and 126-2. In this case, the embedded multi-layer capacitors 126-1 and 126-2 are stacked within substrate 102, such that embedded multi-layer capacitors 126-1 and 126-2 sandwich a set of layers of the routing section of substrate 102. In this case, embedded multi-layer capacitor 126-1 may be a composite capacitor comprising two MIM capacitors (e.g., stacked in an electrical loop with VCSEL chip 104, driver chip 106, and decoupling capacitor 108) with different capacitance values resulting in a first total capacitance value for embedded multi-layer capacitor 126-1. Similarly, embedded multi-layer capacitor 126-2 may be a composite capacitor comprising two MIM capacitors (e.g., separated from embedded multi-layer capacitor 126-1 by the routing section) with different capacitance values resulting in a second total capacitance value (that is different from the first total capacitance value) for embedded multi-layer capacitor 126-1. In some implementations, MIM capacitors positioned closer to the surface electro-optic components (e.g., VCSEL chip 104, driver chip 106, and decoupling capacitor 108) may have a smaller capacitance than MIM capacitors positioned farther from the surface electro-optic components.

As indicated above, FIG. 6 is provided as an example. Other examples may differ from what is described with regard to FIG. 6.

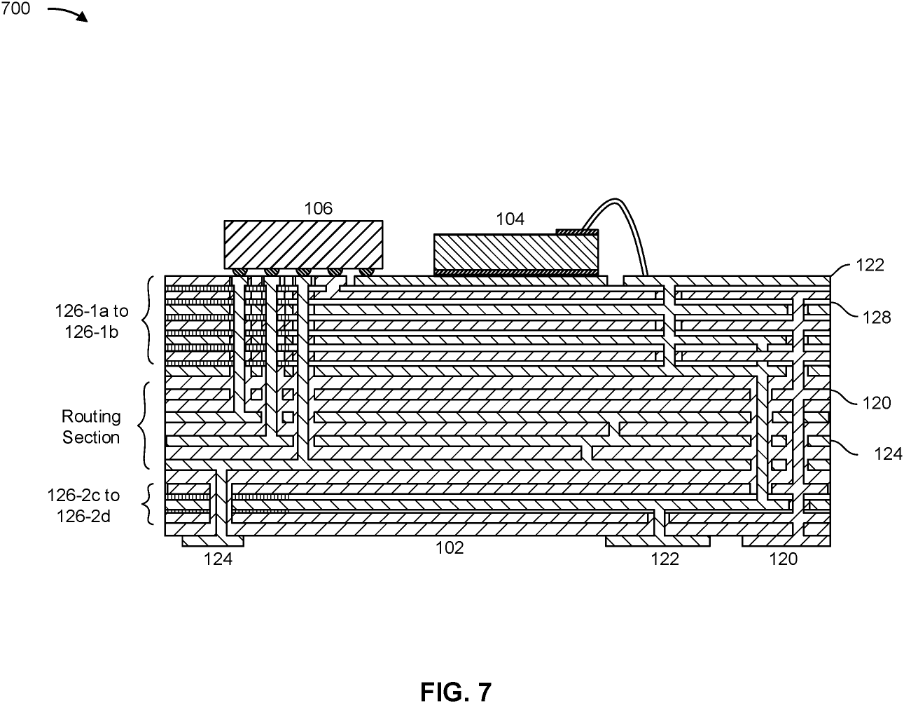

FIG. 7 is a diagram of an example associated with a VCSEL package 700 with multiple embedded MIM capacitors. As shown in FIG. 7, the VCSEL package 700 may include a substrate 102, a VCSEL chip 104, a driver chip 106, and multiple sets of embedded multi-layer capacitors 126-1 (e.g., a first set of embedded multi-layer capacitors 126-1a through 126-1b) and 126-2 (e.g., a second set of embedded multi-layer capacitors 126-2c to 126-2d). In this case, the sets of embedded multi-layer capacitors 126-1 and 126-2 are stacked within substrate 102, such that the sets of embedded multi-layer capacitors 126-1 and 126-2 sandwich the routing section of substrate 102. In this case, by including increased quantities of embedded multi-layer capacitors 126 (e.g., 6 embedded multi-layer capacitors 126-1 and 2 embedded multi-layer capacitors 126-2, as shown), total capacitance from the embedded multi-layer capacitors 126 may be sufficient for operation, thereby enabling decoupling capacitor 108 to be omitted from the VCSEL package 700, which reduces cost and/or package size.

As indicated above, FIG. 7 is provided as an example. Other examples may differ from what is described with regard to FIG. 7.

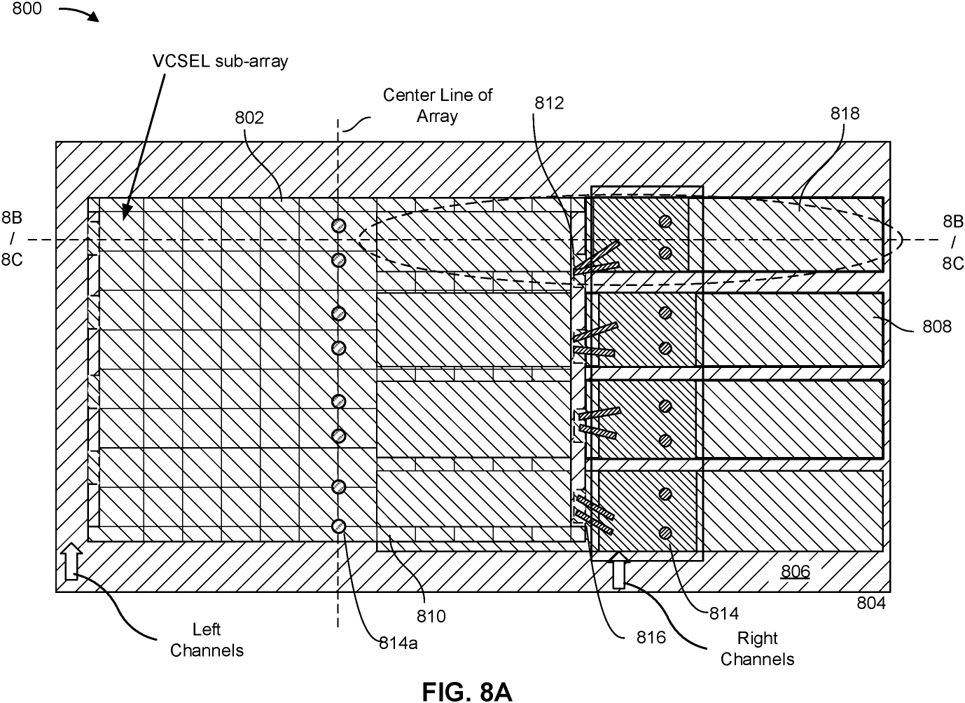

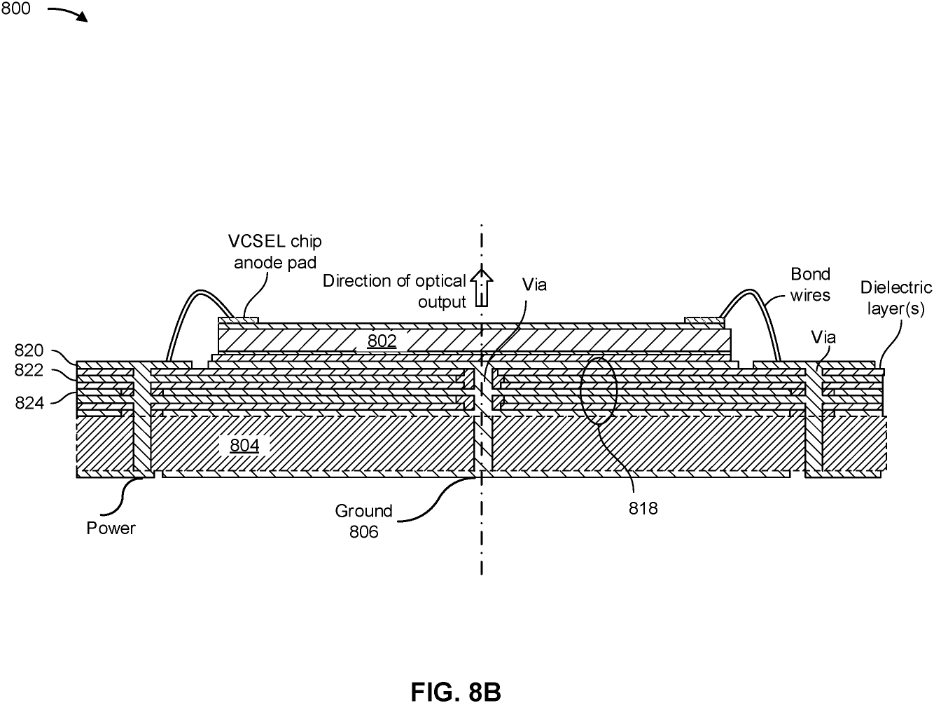

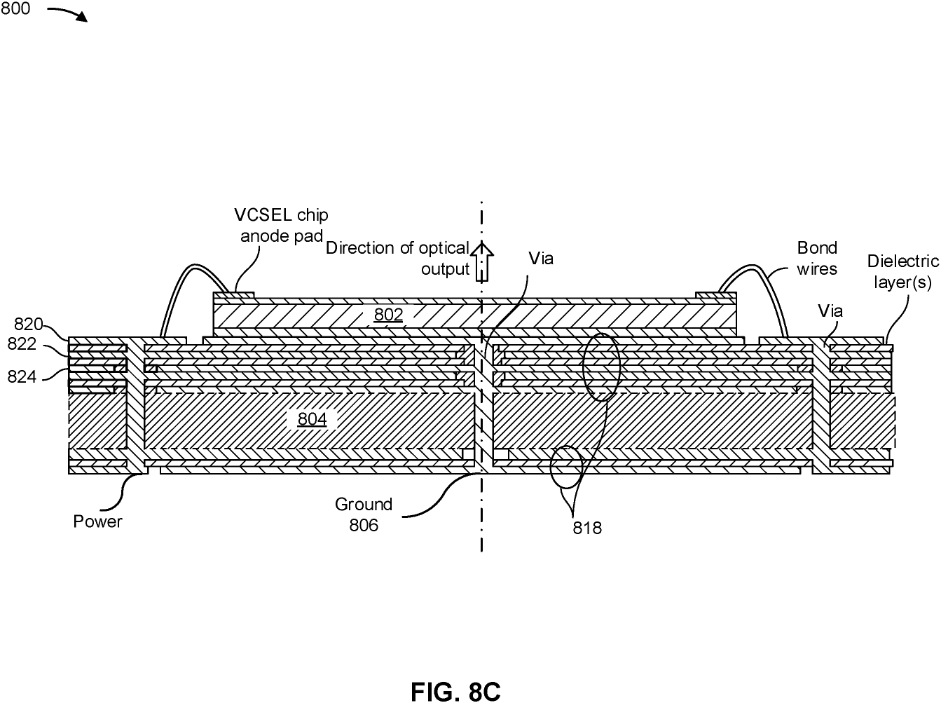

FIGS. 8A-8C are diagrams of an example of an embedded capacitor array for a 2-dimensionally (2D) addressable VCSEL array. In contrast to other VCSEL chips or VCSEL arrays, a 2D addressable VCSEL array includes multiple VCSEL emitters to form an array. For a 2D addressable VCSEL array includes multiple VCSEL arrays to form a 2D array, where each of the sub-array is, itself, a VCSEL array. A 2D VCSEL array may arrange the sub-arrays in an approximate grid arrangement to enable addressing of VCSEL sub-arrays by row and column.

As shown in FIG. 8A, a VCSEL package 800 may include a 2D addressable VCSEL array 802 or a VCSEL sub-array (e.g., a two-dimensionally addressable VCSEL array including multiple VCSEL elements) disposed on a surface of a substrate 804 with one or more ground planes 806 and one or more power planes 808, a cathode 810, an anode 812, a set of power vias 814, a set of ground vias 814a, a set of wire bonds 816, and a multi-layer capacitor 818. Both the cathode 810 and anode 812 are on the surface of the 2D addressable VCSEL array chip. The power vias 814 connect power planes for the multi-layer capacitor 818. The ground vias 814a connect ground planes for the multi-layer capacitor 818. As shown in FIG. 8B, the multi-layer capacitor 818 may be an embedded multi-layer capacitor disposed between the VCSEL array 802 and a routing section of substrate 804. FIG. 8C shows a similar configuration in which the multi-layer capacitor 818 includes multiple sets of embedded multi-layer capacitors sandwiching the routing section. In some implementations, the multi-layer capacitor 818 may include a set of metallic layers 820 (corresponding to power plane 808), 822 (corresponding to power plane 808), and 824 (corresponding to ground plane 806) separated by a set of dielectric layers. By using an embedded multi-layer MIM capacitor within substrate 804, the VCSEL package may omit one or more (e.g., all) MLCC capacitors, thereby achieving a smaller package for a two-dimensionally addressable VCSEL array.

As indicated above, FIGS. 8A-8C are provided as an example. Other examples may differ from what is described with regard to FIGS. 8A-8C.

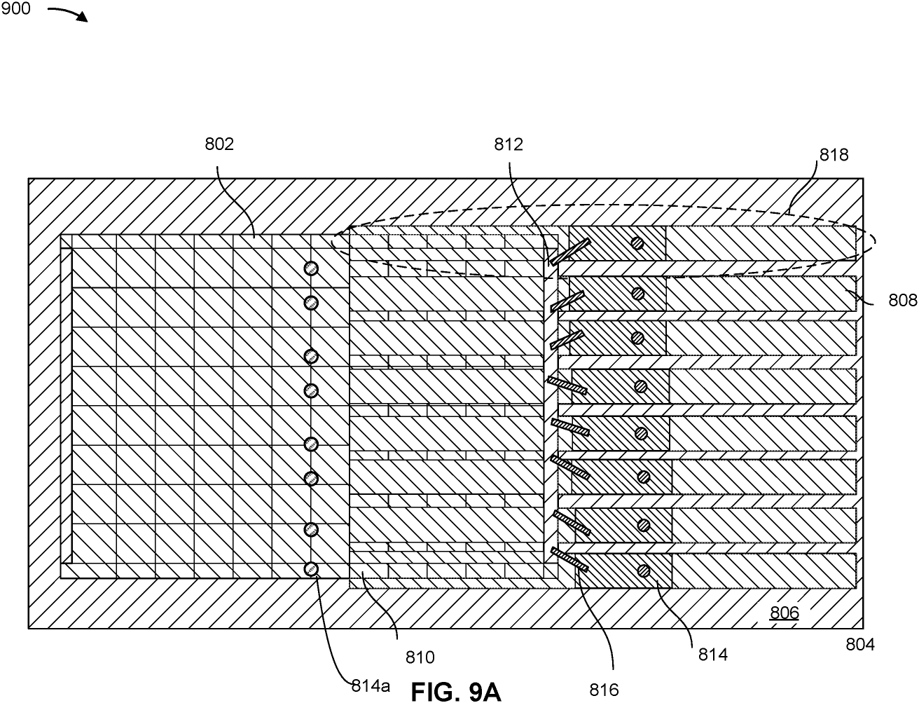

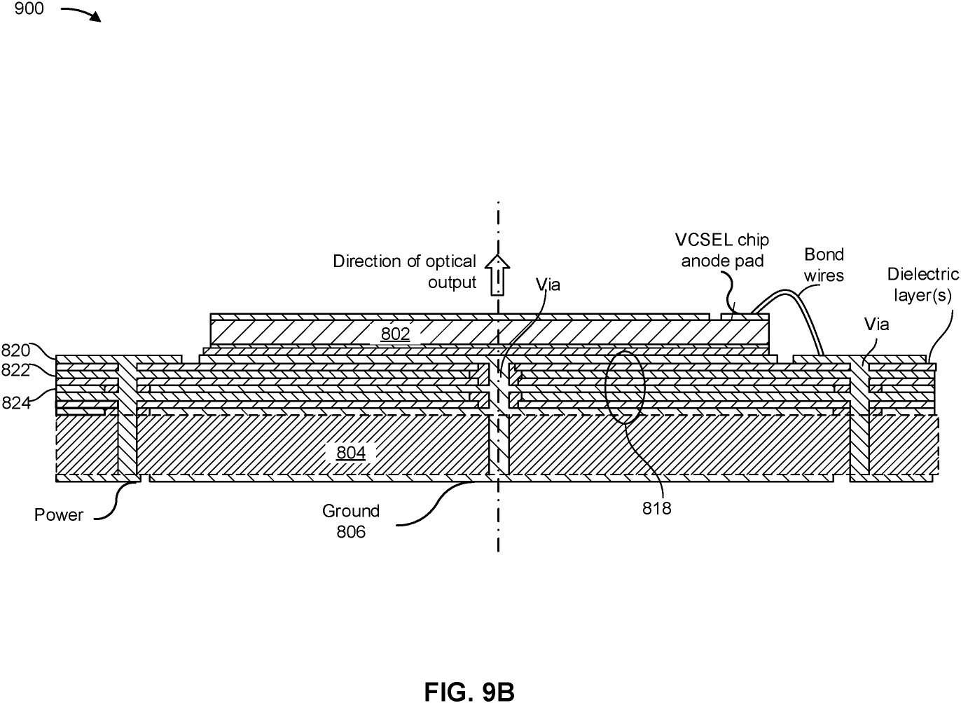

FIGS. 9A-9B are diagrams of an example of an embedded capacitor array for a VCSEL array. As shown in FIG. 9A, a VCSEL package 900 may include a 2D addressable VCSEL array 802 (e.g., a two-dimensionally addressable VCSEL array) disposed on a surface of a substrate 804 with a ground plane 806 and a power plane 808, a cathode 810, an anode 812, a set of vias 814, a set of ground vias 814a, a set of wire bonds 816, and a multi-layer capacitor 818. As shown in FIG. 9B, the multi-layer capacitor 818 may be an embedded multi-layer capacitor disposed between the VCSEL array 802 and a routing section of substrate 804. In some implementations, the multi-layer capacitor 818 may include a set of metallic layers 820 (808), 822 (808), and 824 (806) separated by a set of dielectric layers. As shown in FIGS. 9A and 9B, in contrast to FIGS. 8A-8C, the VCSEL package 900 may have a different bond wire configuration than the VCSEL package 800 based on the multi-layer capacitor 818 being disposed under an entire area of the VCSEL array 802 in the VCSEL package 900. This configuration has all capacitors embedded on one side of the 2D addressable VCSEL chip while the other side is available for other components. A fan-out configuration can be used to spread the embedded capacitors from each other. This may provide additional flexibility in configuration and deployment of VCSEL package 900 than is achieved using MLCC capacitors surface-mounted to a substrate 804.

As indicated above, FIGS. 9A-9B are provided as an example. Other examples may differ from what is described with regard to FIGS. 9A-9B.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

As used herein, satisfying a threshold may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles "a" and "an" are intended to include one or more items, and may be used interchangeably with "one or more." Further, as used herein, the article "the" is intended to include one or more items referenced in connection with the article "the" and may be used interchangeably with "the one or more." Furthermore, as used herein, the term "set" is intended to include one or more items (e.g., related items, unrelated items, or a combination of related and unrelated items), and may be used interchangeably with "one or more." Where only one item is intended, the phrase "only one" or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature’s relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. A vertical cavity surface emitting laser (VCSEL) package, comprising:
a substrate;
a VCSEL disposed on a surface of the substrate;
a VCSEL driver disposed on the surface of the substrate; and
an embedded capacitor electrically connected to the VCSEL and the VCSEL driver,
wherein the embedded capacitor is formed from a subset of layers of the substrate, and
wherein the capacitor is associated with a first capacitance that is different from a second capacitance of at least one other capacitor associated with the substrate.

2. The VCSEL package of claim 1, wherein the embedded capacitor is a metal-insulator-metal (MIM) capacitor.

3. The VCSEL package of claim 2, wherein the other capacitor is at least one other metal-insulator-metal (MIM) capacitor.

4. The VCSEL package of claim 1, wherein the other capacitor is a ceramic capacitor.

5. The VCSEL package of claim 1, wherein the other capacitor is a decoupling capacitor disposed on the surface of the substrate and electrically connected to the embedded capacitor.

6. The VCSEL package of claim 1, wherein the other capacitor is a decoupling capacitor embedded within the substrate and electrically connected to the embedded capacitor.

7. The VCSEL package of claim 1, wherein a layer, of the subset of layers forming the embedded capacitor, forms at least a portion of the surface of the substrate; and
wherein the layer is a dielectric layer directly underneath the VCSEL or a cathode VCSEL.

8. The VCSEL package of claim 1, wherein a direction of a driving current of the VCSEL, VCSEL driver, and embedded capacitor is associated with a first direction, and wherein a direction of a current through a ground plane, associated with a dielectric layer of the embedded capacitor, is associated with a second direction that is opposite the first direction.

9. The VCSEL package of claim 1, wherein a layer, of the subset of layers, is a dielectric layer with a thickness of less than 1 micrometer.

10. A vertical cavity surface emitting laser (VCSEL) substrate, comprising:
a first set of layers including one or more trace routing connections;
a second set of layers forming a metal-insulator-metal (MIM) capacitor,
wherein the second set of layers comprises one or more high dielectric thin layers alternating with one or more ground layers; and
a surface, formed, at least in part, from at least one layer of the second set of layers, to receive at least one electro-optical component,
wherein the at least one electro-optical component includes at least one of a driver, a VCSEL chip, or a decoupling capacitor.

11. The VCSEL substrate of claim 10, wherein the MIM capacitor is a first MIM capacitor, and
wherein the VCSEL substrate further comprises:
a third set of layers forming a second MIM capacitor,
wherein the third set of layers comprises another one or more high dielectric thin layers alternating with another one or more ground layers.

12. The VCSEL substrate of claim 11, wherein the first MIM capacitor and the second MIM capacitor sandwich the first set of layers.

13. The VCSEL substrate of claim 10, further comprising:
a power line trace embedded in the substrate to connect the MIM capacitor to one or more of the at least one electro-optical component.

14. The VCSEL substrate of claim 10, further comprising:
a cathode pad forming at least a portion of the MIM capacitor,
wherein the cathode pad is to receive the VCSEL chip.

15. The VCSEL substrate of claim 10, further comprising:
the decoupling capacitor embedded within the substrate,
wherein the MIM capacitor is disposed between the surface and the decoupling capacitor.

16. The VCSEL substrate of claim 15, wherein the at least one electro-optical component, the MIM capacitor, and the decoupling capacitor form an inductive current loop with less than a threshold amount of inductance.

17. A vertical cavity surface emitting laser (VCSEL) package, comprising:
a substrate;
a VCSEL disposed on a surface of the substrate;
a VCSEL driver disposed on the surface of the substrate; and
a set of embedded capacitors electrically connected to the VCSEL and the VCSEL driver,
wherein the set of embedded capacitors is formed from a subset of layers of the substrate,
wherein an embedded capacitor, of the set of embedded capacitors, is associated with a first capacitance that is different from a second capacitance of another capacitor of the set of embedded capacitors.

18. The VCSEL package of claim 17, wherein the set of embedded capacitors is stacked in an electrical loop with the VCSEL driver, the VCSEL, and a decoupling capacitor disposed on the surface of the substrate.

19. The VCSEL package of claim 17, wherein a first subset of the set of embedded capacitors is stacked in an electrical loop with the VCSEL driver, the VCSEL, and a decoupling capacitor disposed on the surface of the substrate, and
wherein a second subset of the set of embedded capacitors is separated from the first subset of the set of embedded capacitors by a routing section of the substrate.

20. The VCSEL package of claim 17, wherein the VCSEL is a two-dimensionally addressable VCSEL array including a plurality of VCSEL elements, and
wherein one or more embedded capacitors, of the set of embedded capacitors, are embedded under a first subset of the plurality of VCSEL elements and not under a second subset of the plurality of VCSEL elements, such that a first total capacitance is associated with the first subset of the plurality of VCSEL elements and a second total capacitance, that is different from the first total capacitance, is associated with the second subset of the plurality of VCSEL elements.
